(19) United States
(12) Patent Application Publication
(10) Pub. No.: US 2009/0039529 A1
(43) Pub. Date: Feb. 12, 2009

(54) Integrated Circuit Having a Plurality of Connection Pads and Integrated Circuit Package

(76) Inventors: Sebastian Mueller, Langebrueck (DE); Thomas Hein, Munich (DE)

Correspondence Address: SLATER & MATSIL, L.L.P., 17950 PRESTON ROAD, SUITE 1000, DALLAS, TX, 75252, US

(21) Appl. No.: 11/835,967

(22) Filed: Aug. 8, 2007

(51) Int. Cl. H01L 23/48; H01L 21/02

(52) U.S. Cl. 257/778; 438/108; 257/E23.004; 257/E21.598

(57) ABSTRACT

In accordance with an embodiment of the invention, an integrated circuit including a plurality of connection pads is provided, wherein a first connection pad is configured in accordance with a first contacting technology, and wherein a second connection pad is configured in accordance with a second contacting technology. The second contacting technology is different from the first contacting technology.

### TECHNICAL FIELD

Embodiments of the invention relate to an integrated circuit comprising a plurality of connection pads and to an integrated circuit package.

### BACKGROUND

In the production of electronic components, which include integrated circuits and which are for example suitable as surface mount devices, conventionally, circuits are created in a wafer by using appropriate technologies first, thereby to provide circuit arrangements, wherein connection pads are applied to the surface of the circuit arrangements or chips for an electrical connection to external contact devices.

At present, die, wire-bond, and flip-chip are conventionally used as contacting technologies for integrated circuit mounting or integrated circuit packaging, by means of which the integrated circuits are electrically conductively connected to a substrate or carrier. The single integrated circuit or several integrated circuits which are connected to a substrate are typically embedded in a suitable material, wherein the lower side of the substrate comprises appropriate contacting elements by means of which the package can be mounted to a printed circuit board (PCB), for example. An integrated circuit (IC), sometimes also referred to as a chip, e.g., a microchip, may be understood as a semiconductor wafer on which thousands or millions of resistors, capacitors, and transistors may be fabricated.

In a conventional surface mounting technology, so-called board-on-chip packaging (BOC) is used. In this technology, in which the chip is arranged face down on a substrate, the chip includes in its center the connection pads which are bonded through a slot in the substrate by means of bond wire to contacts on the lower side of the substrate. This mounting technology is used for packaging of memory chips, for example.

In another conventional chip contacting technology, for example, the flip-chip mounting technology is used, in which the connection pads of the chips are provided with respective contacts on the wafer level, for example with solder bumps, and the chip is arranged face down on a substrate.

### BRIEF DESCRIPTION OF THE DRAWINGS

In the drawings, the same reference characters generally refer to the same parts throughout the different views. The drawings are not necessarily drawn to scale; instead, emphasis is generally placed on illustrating the principles of the invention. In the following description, various embodiments of the invention are described with reference to the following drawings, in which:

FIG. 1 shows an integrated circuit having a plurality of connection pads in accordance with an embodiment of the invention; and

FIG. 2 shows an integrated circuit package in accordance with an embodiment of the invention.

### DETAILED DESCRIPTION OF ILLUSTRATIVE EMBODIMENTS

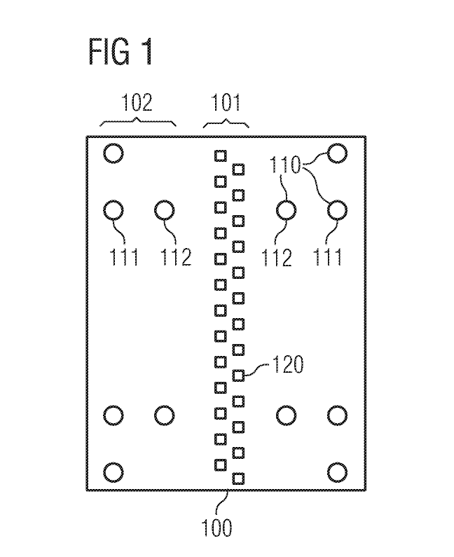

FIG. 1 shows an integrated circuit 100 according to an embodiment of the invention.

An integrated circuit (IC), sometimes also referred to as a chip, e.g., a microchip, may be a semiconductor wafer on which thousands or millions of resistors, capacitors, and transistors may be fabricated.

In this embodiment, the chip 100 includes on an upper side a plurality of connection pads 110, 120, wherein first connection pads 120 in the center region 101 of the chip 100 are configured for bonding by means of a bond wire, and second connection pads 110 in a second region 102 that is outside the center region 101 are configured as flip-chip contacts. According to an embodiment of the invention, the second connection pads 110 arranged in the second region 102 could be connections 112 for applying a first power supply potential, e.g., VSS, and, in general, connections 111 for applying a second power supply potential, e.g., VDD, and/or connections for applying a reference potential and connections for applying an auxiliary supply (VPP) by means of which an electric voltage can be supplied to the chip 100 for power supply, while the connection pads 120 arranged in the center region 101 are connections for address, control and data signals. In other words, the connection pads 120 arranged in the center region 101 serve to supply address signals, control signals, data signals and in some cases power supply connections to the chip 100. However, it is also possible that the connection pads 110 outside the center region 101 are, e.g., connections for status signals, for bonding scan or mirror functions, since a highest possible signal transmission rate is not required with these types of signals. This means that depending on the respective design of the integrated circuit, such connection pads for, e.g., connections for status signals, for bonding scan or mirror functions, may be redistributed starting from a position, which may be predetermined during the design, to edge regions of the chip, e.g., by means of a so-called redistribution layer (RDL) which may be arranged on the chip 100. Such connection pads may then be configured as flip-chip contacts. However, in an alternative embodiment of the invention, it is also possible that these connections for, e.g., status signals, for bonding scan or mirror functions may be provided starting from a position which may be predetermined during the design of the chip within the chip substrate to a region outside the center region 101. These connections may then be configured as flip-chip contacts.

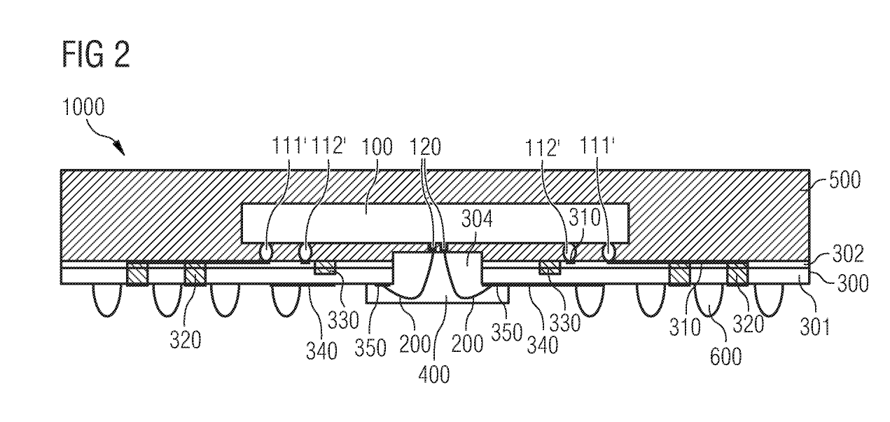

The connection pads 111, 112 are provided with contacting elements suitable for flip-chip mounting, such as solder bumps, plated bumps or stud bumps, which may for example be applied during one of the conventional bumping processes on the wafer level to the connection pads 111, 112, and which are configured to contact the chip 100 with corresponding contacts of a substrate. The number of connection pads 111 and 112 for power supply of the chip 100 is not limited to the number shown in the drawing, but depends on the respective application purpose (certain parameters) for which the respective chip 100 is intended to be used. Due to the fact that in the embodiment shown, first power supply (e.g., VSS) connections 112 and second power supply (e.g., VDD) connections 111 are provided with bumps 112′ and 111′ (FIG. 2), the bumping layout is relaxed, since there are relaxed limitations with regard to the pitches in the design and mass-production of the bumps 111′ and 112′. It is consequently typically not necessary to carry out a redistribution for the connection pads 111 and 112 on the chip 100.

The connection pads 120 for wire bonding as well as the connection pads 110 for flip-chip mounting are disposed directly at the circuit inputs/circuit outputs (direct connections) of the chip 100. In other words, the connection pads 110, 120 are not connection pads redistributed for example by means of a redistribution layer, which have been newly positioned on the chip 100. Due to a chip design, in which the connection pads 120 for address, control and data signals are disposed in the center region 101 of the chip 100 and the connection pads 111, 112 for power supply are disposed in the second region 102 of the chip 100, in accordance with the manufacturing, these connection pads 111, 112 can be provided so as to be correspondingly larger than the connection pads 120 in the center region 101, because in the second region 102, i.e., in the chip portions disposed outside the center region 101, there is enough space on the chip 100 to provide the connection pads 111, 112 for applying voltage so as to be larger than the connection pads 120 in the center of the chip 100.

The chip 100 according to an embodiment may, for example, be formed as a memory chip comprising volatile and/or non-volatile memory cells.

In the context of this description, a “volatile memory cell” may be understood as a memory cell storing data, the data being refreshed during a power supply voltage of the memory system being active, in other words in a state of the memory system in which it is provided with power supply voltage.

A “non-volatile memory cell” may be understood as a memory cell storing data even if it is not active. In an embodiment of the invention, a memory cell may be understood as not being active, for example, if currently access to the content of the memory cell is inactive. In another embodiment, a memory cell may be understood as not being active, for example if the power supply is inactive. Furthermore, the stored data may be refreshed on a regular timely basis, but not every few picoseconds or nanoseconds or milliseconds as with a “volatile memory cell”, but rather in a range of hours, days, weeks or months.

In an embodiment of the invention, memory cells may in addition be provided as multi-bit memory cells and/or as multi-level memory cells.

As used herein, the term “multi-bit” memory cell is intended to include, for example, memory cells which are configured to store a plurality of bits by spatially separated electric charge storage regions or current conductivity regions, thereby representing a plurality of logic states.

As used herein, the term “multi-level” memory cell is intended to include, for example, memory cells which are configured to store a plurality of bits by showing distinguishable voltage or current levels depending on the amount of electric charge stored in the memory cell or the amount of electric current flowing through the memory cell, thereby representing a plurality of logic states.

According to another embodiment, the chip 100 may also comprise logic cells, which are, for example, connected to logic gates, and which are therefore such that they realize one or a plurality of pre-determined functions. Thus, the logic cells may be connected to programmable processors, for example to ASICs or to a microprocessor, wherein a microprocessor may for example be provided as a complex instruction set computer (CISC) processor or as a reduced instruction set computer (RISC) processor or as a processor of any other architecture.

FIG. 2 shows a chip package according to an embodiment of the invention.

FIG. 2 shows a chip package 1000 according to an embodiment, comprising a substrate 300 having contacts 600 on its lower side, and a chip 100 arranged on the substrate 300, having a plurality of connection pads 111, 112, 120 (see FIG. 1) which are electrically connected to the contacts 600 on the lower side of the substrate 300, wherein first connection pads 120 which are disposed in the center region of the chip 100 are connected to the contacts 600 on the lower side of the substrate 300 by means of a bond wire 200, and second connection pads 111, 112, which are arranged outside the center region are connected to the contacts 600 on the lower side of the substrate 300 by means of flip-chip mounting.

The chip package 1000 shown has a generally flat architecture, in which the electrical connections can be established via a ball grid array (contacts 600), for example. However, it is also possible to provide the electrical connections in the form of pins.

In an embodiment of the invention, the chip package 1000 includes the chip 100 and the substrate 300. The chip 100 mounted face down on the substrate 300 includes first connection pads 120 for supplying address, control and data signals, or additional power connections, which are arranged in the center region (101, FIG. 1) of the chip 100 in one, two or more adjoining rows, for example. In the context of this description center region 101 is meant to be a region of the chip 100, in which the connection pads are typically arranged in the context of a wire bonding. In an embodiment of the invention the center region 101 is a rectangular region, in general a region of any shape. In an embodiment of the invention the center region 101 is provided in a region of approximately 300 μm to approximately 1,500 μm in a first direction, and in a region of approximately 5,000 μm to approximately 14,000 μm in a second direction substantially perpendicular to the first direction around the center of the surface of the chip 100 (in the case of a rectangular center region 101).

In addition, in an embodiment of the invention, the chip 100 includes second connection pads 111, 112 for supplying energy supply voltage, which are arranged outside the center region (102, FIG. 1). The connection pads 120 and the connection pads 111, 112 are respectively arranged directly at circuit inputs of the chip 100, such that a redistribution need not be carried out for the connection pads 120, 111 and 112, although, if desired, a redistribution may be provided in an alternative embodiment of the invention. In the embodiment shown, the substrate 300 comprises two substrate layers 301 and 302 and a bond slot 304. According to an embodiment of the invention, the chip 100 is placed on the substrate 300, such that the center region of the chip 100 comprising the connection pads 120 is disposed in the region of the bond slot 304. On the side of the substrate 300 facing away from the chip 100, contact elements 600 are disposed. As shown in FIG. 2, these contact elements 600 may be solder balls.

The connection pads 120 in the center region of the chip 100 are each bonded individually by means of a bond wire 200 to corresponding portions 350 of conductor traces disposed on the lower side of the substrate 300, which are connected via a conductor trace arrangement to the contact elements 600. The bonding itself is carried out by means of one of the actually conventional wire bonding technologies, such as wedge/wedge bonding or ball/wedge bonding, for example by using a thermo-compression method and/or an ultrasonic method.

The electrical connection of the connection pads 111 and 112 arranged in a distributed manner outside the center region or of the bumps 111′ and 112′ arranged at the connection pads 111, 112, with the contact elements 600 accordingly provided for this purpose, is provided, for example, via conductor traces 310 on the side of the substrate 300 facing the chip 100, through vias 320, blind top vias 330, blind bottom vias (not shown), and conductor traces 340 disposed on the lower side of the substrate 300. In an embodiment of the invention, a blind top via may be understood as a via, which may extend for example from the upper surface of the substrate (e.g., of the substrate 300 having two layers) facing the chip to, e.g., the bottom side of the upper one of the two layers of the substrate, wherein the bottom end of the via may be coupled with a trace, which may be guided from the bottom end of the via to a desired position between the layers. In an embodiment of the invention, a blind bottom via may be formed at such a position, which may extend from the bottom side of the substrate through the bottom layer of the substrate (e.g., of the substrate 300 having two layers) and which may be electrically coupled with the trace. In this arrangement of such vias, a high wiring density may be achieved if this is desired. The vias may, e.g., be formed directly in the pad.

Due to the fact that in the embodiment shown only the VDD connections and the VSS connections arranged in a distributed manner outside the center region are electrically connected to the contact elements 600 on the lower side of the substrate 300 by means of the flip-chip technology, it is sufficient to use a substrate 300 having two layers 301, 302. In the case of an appropriate chip design, a one-layer substrate for example might also be suitable for carrying out or providing the electrical connections between the VDD connections/VSS connections and the contact elements 600. Additional substrate layers for power supply, e.g., VSS or VDD planes or planes for the status signals, the bonding scan or mirror functions may also be required by chip or package design.

The chip package 1000 further includes a housing portion 500 of a suitable material, which is connected to the substrate 300 and, conventional as such, in which the chip 100 is embedded. Furthermore, the bond wires 200 are embedded in a sealing material 400 which can enclose the connection portions 350 for the bond wires 200 on the lower side of the substrate 300.

In the case of a chip package 1000 comprising a chip 100 and a substrate 300 according to an embodiment of the invention, two different connection technologies are realized for electrically connecting the chip 100 to the contacts 600 of the substrate 300, wherein the effects of each of the connection technologies are clearly shown, while at the same time the negative effects of the same are reduced. In this regard, general positive effects of the flip-chip mounting technology and the wire bond mounting technology are used for example, and low costs are generated, such that the chip package 1000 may be manufactured at a lower cost in some cases than would be possible in the case of a mounting by using the flip-chip mounting technology only, which will be explained hereinafter in detail.

By connecting the connection pads 120 of the address, control and data signal connections of the chip 100 by means of wire bonding to the connections or conductor traces of the substrate 300, a short and therefore fast signal distribution may be provided, such that variations or instabilities in signal transmission can be kept at a relatively low level, e.g., at the lowest possible level even with a high transmission speed, i.e., with high clock rates. Moreover, no vias are required in the wire bond process for the lines from the upper side facing the chip 100 to the lower side of the substrate 300, whereby on the one hand, parasitic effects can be reduced, and on the other hand a cost-effective substrate having only a few, for example two, layers can be used. The already existing spine architecture with regard to the connection pads 120 existing in the center region may be used. In addition, it is therefore not required to redistribute the connection pads 120 which conventionally are located in the center region to other regions by means of an additional redistribution layer, as this would be necessary, for example, for arranging the bumps for a flip-chip mounting of the connection pads 120, for example for high-speed electronic devices.

By connecting the connection pads 111, 112 of the, e.g., VSS and VDD, respectively, connections of the chips by means of flip-chip technology to the connections or conductor traces of the substrate 300, it is not necessary to carry out a redistribution of the, e.g., VSS and VDD connections into the center area of the chip 100, which, conventionally, are located outside the center region of the chip 100, as this would be necessary if the connection pads 111, 112 were connected to the contacts 600 of the substrate 300 by means of wire bonding, wherein in addition multiple wire bond connections would be required for the, e.g., VSS and VDD connection wires. Due to the fact that in an embodiment of the invention only the power supply connections, e.g., VSS and VDD connections in the chip 100, which for example may be configured larger in size than the connection pads 120 for the address, control and data signals due to sufficient space on the chip 100, are provided with bumps in the waferbumping process without additional costs, no special requirements have to be fulfilled for the realization with regard to necessary pitches between the bumps, such that standard substrate design rules for relaxed bump pitches may be used instead of requiring an expensive substrate manufacturing or assembly, because in addition, a substrate 300 can be used for the chip package, which could be realized with just two conductive layers, because only the connections of the VSS and VDD connections have to be realized through the substrate. Since the connection pads 110, 111 are mounted outside the center region by means of flip-chip technology with the corresponding connections on the upper surface of the substrate 300, it is typically not necessary to arrange an adhesion layer between the chip 100 and the substrate 300 to fix the chip 100 on the substrate 300, since the chip is held in its position by means of the solder connection of the bumps 111′ and 112′ with the corresponding connections on the substrate 300.

In summary, the chip and the chip package according to an embodiment of the invention in which a chip is bonded to a substrate by means of two different bonding technologies show an increased functionality and lower costs in some cases. In another case, increased flexibility of design and/or performance may be obtained. Still other positive effects and utility will be apparent to persons of skill in the art in specific cases. This means that by the two connection technologies used, the transmission for example of the DRAM core power and the high-speed section power can be realized separately. The combination of for example wire bond technology and flip-chip technology for bonding a chip, which may for example be used for commodity DDR3 with large densities (≧2 Gbit), may be less expensive than the use of only one of these two technologies. Moreover, the chip or the chip package with the chip can be a multiple-access memory, for example a dynamic random access memory (DRAM), a static random access memory (SRAM), a magneto-resistive random access memory (MRAM), a conductive bridging random access memory (CBRAM), a phase change random access memory (PCRAM), or a flash memory, such as a charge storage memory (for example a floating gate memory or a charge trapping memory).

According to an embodiment, a chip includes a plurality of connection pads, wherein at least a first connection pad is disposed in the center region of the chip being configured as a wire bond connection pad, and at least a second connection pad is disposed outside the center region, which is configured as a flip-chip contact.

According to another embodiment, a chip package includes a substrate having contacts on a lower side, and a chip disposed on the substrate having a plurality of connection pads which are electrically conductively connected to the contacts on the lower side of the substrate, wherein first connection pads which are disposed in the center region of the chip are connected to the contacts on the lower side of the substrate by means of wire bonding, and second connection pads which are disposed outside the center region are connected to the contacts on the lower side of the substrate by means of flip-chip mounting.

According to another embodiment, a memory module comprises a multiplicity of integrated circuits, wherein at least one integrated circuit of the multiplicity of integrated circuits comprises a plurality of connection pads, wherein at least a first connection pad, which is arranged in the center region of the integrated circuit, is configured as a wire bond connection pad; and wherein at least a second connection pad, which is arranged outside the center region of the integrated circuit, is configured as a flip-chip contact. The memory module may be a stackable memory module in which at least some of the integrated circuits are stacked one above the other.

While the invention has been shown and described in particular with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. An integrated circuit comprising:
a first connection pad, arranged in a center region of the integrated circuit, the first connection pad configured as a wire bond connection pad; and
a second connection pad, arranged outside the center region of the integrated circuit, the second connection pad configured as a flip-chip contact.

2. The integrated circuit of claim 1, wherein the first and second connection pads are formed on one side of the integrated circuit.

3. The integrated circuit of claim 1, wherein the first and second connection pads are arranged directly at circuits formed in the integrated circuit.

4. The integrated circuit of claim 1, wherein the first connection pad comprises an address, control or data signal connection.

5. The integrated circuit of claim 1, wherein the second connection pad comprises a bump produced in the wafer bumping process.

6. The integrated circuit of claim 1, wherein the second connection pad comprises a power supply connection.

7. The integrated circuit of claim 6, wherein the second connection pad comprises a VDD connection.

8. The integrated circuit of claim 6, wherein the second connection pad comprises a VSS connection.

9. The integrated circuit of claim 1, wherein the integrated circuit comprises a memory integrated circuit.

10. The integrated circuit of claim 1, further comprising volatile or non-volatile memory cells disposed at a surface of the integrated circuit.

11. The integrated circuit of claim 1, further comprising logic cells disposed at a surface of the integrated circuit.

12. The integrated circuit of claim 1, wherein the second connection pad is larger than the first connection pad.

13. The integrated circuit of claim 1, wherein the first and second connection pads are formed without a redistribution layer.

14. An integrated circuit package, comprising:
a substrate having contacts at a lower side; and
an integrated circuit arranged on the substrate, the integrated circuit comprising a plurality of connection pads which are electrically connected to the contacts on the lower side of the substrate;
wherein first connection pads which are arranged in a center region of the integrated circuit are connected to the contacts on the lower side of the substrate by means of wire bonding; and
wherein second connection pads which are arranged outside the center region of the integrated circuit are connected to the contacts on the lower side of the substrate by means of flip-chip mounting.

15. The integrated circuit package of claim 14, wherein the substrate comprises a slot, through which the first connection pads in the center region of the integrated circuit are bonded to the contacts at the lower side of the substrate.

16. The integrated circuit package of claim 14, wherein the second connection pads are arranged at power supply connections.

17. The integrated circuit package of claim 16, wherein the second connection pads are arranged at VDD connections.

18. The integrated circuit package of claim 16, wherein the second connection pads are arranged at VSS connections.

19. The integrated circuit package of claim 14, wherein the first connection pads comprise address, control and data signal connections.

20. The integrated circuit package of claim 14, wherein the first and second connection pads are arranged directly at circuits of the integrated circuit.

21. The integrated circuit package of claim 14, wherein the substrate comprises a minimum of two layers.

22. The integrated circuit package of claim 14, wherein the second connection pads outside the center region of the integrated circuit are larger than the first connection pads in the center region of the integrated circuit.

23. The integrated circuit package of claim 14, wherein the integrated circuit comprises a memory integrated circuit.

24. The integrated circuit package of claim 14, wherein no adhesive is provided between the integrated circuit and the substrate.

25. The integrated circuit package of claim 14, wherein the first and second connection pads are formed without a redistribution layer.

26. An integrated circuit comprising:
a first connection pad configured in accordance with a first contacting technology; and
a second connection pad configured in accordance with a second contacting technology, wherein the second contacting technology is different from the first contacting technology.

27. The integrated circuit of claim 26, wherein the first contacting technology comprises wire bonding.

28. The integrated circuit of claim 26, wherein the second contacting technology comprises flip-chip mounting.

29. The integrated circuit of claim 26, wherein the first and second connection pads are provided on a same side of the integrated circuit.

30. The integrated circuit of claim 26, wherein the first and second connection pads are formed without a redistribution layer.

31. A method for manufacturing an integrated circuit comprising a plurality of connection pads, the method comprising:
forming at least a first connection pad in a center region of the integrated circuit, wherein the first connection pad is configured as a wire bond connection pad; and
forming at least a second connection pad outside the center region of the integrated circuit, wherein the second connection pad is configured as a flip-chip contact.

32. A method for manufacturing an integrated circuit comprising a plurality of connection pads, the method comprising:
forming a first connection pad in accordance with a first contacting technology; and
forming a second connection pad in accordance with a second contacting technology, wherein the second contacting technology is different from the first contacting technology.

33. The method of claim 32, wherein the first contacting technology comprises wire bonding.

34. The method of claim 32, wherein the second contacting technology comprises flip-chip mounting.

35. The method of claim 32, wherein the first and second connection pads are formed on positions of the integrated circuit without a redistribution layer.

36. A memory module, comprising:
a plurality of integrated circuits, wherein at least one integrated circuit of the plurality of integrated circuits comprises a plurality of connection pads,
wherein at least a first connection pad, which is arranged in a center region of the integrated circuit, is configured as a wire bond connection pad; and
wherein at least a second connection pad, which is arranged outside the center region of the integrated circuit, is configured as a flip-chip contact.

37. The memory module of claim 36, wherein the memory module is a stackable memory module in which at least some of the plurality of integrated circuits are stacked one above the other.
